(19) United States
(12) Patent Application Publication
(10) Pub. No.: US 2006/0189131 A1
(43) Pub. Date: Aug. 24, 2006

(54) Composition and process for element displacement metal passivation

(75) Inventors: Chung-Liang Chang, Hsinchu (TW); Shaulin Shue, Hsinchu (TW); Ming-Hsing Tsai, Taipei (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 11/067,042

(22) Filed: Feb. 24, 2005

(51) Int. Cl. H01L 21/44; H01L 21/302

(52) U.S. Cl. 438/678; 438/745

(57) ABSTRACT

A composition and process suitable for the passivation of metal lines, layers or surfaces, particularly for the passivation of copper in the fabrication of integrated circuit devices on wafer substrates. The process includes providing a novel composition solution in contact with a copper line, layer or surface on a substrate as the copper is subjected to chemical mechanical planarization (CMP). The composition includes reactive cations of a displacement metal which are suspended in solution and spontaneously displace the copper atoms in the copper in an oxidation/reduction reaction. The oxidized and displaced copper cations are carried away by the composition solution, and the newly-incorporated metal atoms in the copper substantially inhibit or prevent growth of copper oxides in the copper.

### FIELD OF THE INVENTION

The present invention relates to passivation of metal layers in the fabrication of integrated circuit devices on semiconductor wafer substrates. More particularly, the present invention relates to a composition and process for passivation of a metal layer such as copper on a substrate by displacing some of the metal atoms in the layer with other metals to render the copper or other metal layer more resistant to oxidation, extend process Q-time and enhance layer electro-migration.

### BACKGROUND OF THE INVENTION

The fabrication of various solid state devices requires the use of planar substrates, or semiconductor wafers, on which integrated circuits are fabricated. The final number, or yield, of functional integrated circuits on a wafer at the end of the IC fabrication process is of utmost importance to semiconductor manufacturers, and increasing the yield of circuits on the wafer is the main goal of semiconductor fabrication. After packaging, the circuits on the wafers are tested, wherein non-functional dies are marked using an inking process and the functional dies on the wafer are separated and sold. IC fabricators increase the yield of dies on a wafer by exploiting economies of scale. Over 1000 dies may be formed on a single wafer which measures from six to twelve inches in diameter.

Various processing steps are used to fabricate integrated circuits on a semiconductor wafer. These steps include deposition of a conducting layer on the silicon wafer substrate; formation of a photoresist or other mask such as titanium oxide or silicon oxide, in the form of the desired metal interconnection pattern, using standard lithographic or photolithographic techniques; subjecting the wafer substrate to a dry etching process to remove the conducting layer from the areas not covered by the mask, thereby etching the conducting layer in the form of the masked pattern on the substrate; removing or stripping the mask layer from the substrate typically using reactive plasma and chlorine gas, thereby exposing the top surface of the conductive interconnect layer; and cooling and drying the wafer substrate by applying water and nitrogen gas to the wafer substrate.

The numerous processing steps outlined above are used to cumulatively apply multiple electrically conductive and insulative layers on the wafer and pattern the layers to form the circuits. The final yield of functional circuits on the wafer depends on proper application of each layer during the process steps. Proper application of those layers depends, in turn, on coating the material in a uniform spread over the surface of the wafer in an economical and efficient manner.

In the semiconductor industry, copper is being increasingly used as the interconnect material for microchip fabrication. The conventional method of depositing a metal conducting layer and then etching the layer in the pattern of the desired metal line interconnects and vias cannot be used with copper because copper is not suitable for dry-etching. Special considerations must also be undertaken in order to prevent diffusion of copper into silicon during processing. Therefore, the dual-damascene process has been developed and is widely used to form copper metal line interconnects and vias in semiconductor technology. In the dual-damascene process, the dielectric layer rather than the metal layer is etched to form trenches and vias, after which the metal is deposited into the trenches and vias to form the desired interconnects. Finally, the deposited copper is subjected to chemical mechanical planarization (CMP) to remove excess copper (copper overburden) extending from the trenches.

While copper has certain advantages over aluminum and other metals traditionally used in the fabrication of metal lines on substrates, the use of copper in semiconductor fabrication has certain drawbacks. For example, copper tends to diffuse rapidly through standard semiconductor insulators and into silicon, contaminating pn junctions and causing failure of the integrated circuit. Thus, diffusion barriers which completely surround copper conductors are frequently necessary to solve this problem.

Another difficulty posed by copper-based metallurgy is the tendency of native oxides to form on exposed regions of copper. Copper cannot be exposed for extended periods of time to oxidizing atmospheres without jeopardizing the integrity of interconnections. Copper oxides grow at a rate of 20 angstroms in the first minute within an air environment, and at a rate of 50 angstroms per minute in a water environment. Because the copper region is used to electrically interconnect various devices within an electrical circuit, the formation of the oxides on the copper presents an undesirable reduction of electrical conductance through the copper region. Therefore, various processing approaches unique to copper metallurgy-based manufacturing processes are frequently used to control, mitigate or limit the effects of oxide growth on copper.

In the dual damascene process, both vias and metal lines for each metal layer are created by etching holes and trenches in a dielectric layer. Copper is deposited into the etched features to form the metal lines in the trenches and the vias through the holes to interconnect the metal lines. Excess copper, or copper overburden, is removed using chemical mechanical planarization (CMP).

After the CMP step, additional horizontally-extending metal lines connected by vertically-extending vias may be sequentially fabricated on the planarized copper layer. Accordingly, an etch stop layer, such as silicon nitride (SiN), is initially deposited on the planarized copper layer, after which an intermetal dielectric (IMD) layer is deposited on the etch stop layer for the etching of via openings therethrough to the etch stop layer. The via openings are ultimately filled in with copper to establish vertical interconnections between the planarized copper layer, which serves as a horizontally-extending metal line, and additional horizontally-extending metal lines fabricated in trenches above the vias.

However, a delay period typically exists between the completion of chemical mechanical planarization and deposition of the etch stop layer on the planarized copper layer. During this delay period, the planarized copper is exposed to ambient oxygen in the environment, such that copper oxides rapidly form on the copper surface. These copper oxides present significant resistance to electrical migration of current through the metal line that is ultimately defined by the planarized copper layer, thus substantially reducing surface electro-migration and potentially leading to failure of the fabricated IC device. As shown in FIG. 1, the atomic percentage of oxygen on the surface of a copper layer (having a copper atomic percentage of 60% and greater) can be as high as 20% when the copper is exposed to ambient air.

Conventional approaches to minimizing oxidation of planarized copper during IC fabrication have included BTA (benzotriazole) passivation and deposition of electroless CoWP (cobalt-tungsten-phosphorous alloy) and tungsten. BTA passivation involves deposition of a benzotriazole film on the planarized copper after CMP and prior to deposition of an etch stop layer on the copper for higher-order metal line and via fabrication. Over the last 5 years, use of electroless CoWP as a cap layer for metals in semiconductor fabrication has attracted much attention from researchers. However, both of these methods suffer from various drawbacks including inordinate process complexity, difficulty in maintaining chemical integrity and selective loss during deposition, for example. Accordingly, a new and improved process for the passivation of copper lines is needed during the fabrication of IC devices. A new and improved process is further needed which eliminates or substantially reduces electro-migration failure in IC devices by significantly improving surface migration of electrical current on copper lines in the devices.

It is an object of the present invention to provide a novel composition and process which is suitable for the passivation of metal lines, layers or surfaces in the fabrication of IC devices.

Another object of the present invention is to provide a novel composition and process which facilitates or enhances electro-migration in metal lines, layers or surfaces of IC devices.

Still another object of the present invention is to provide a novel composition and process suitable for providing a substantially oxide-free cap layer for a metal line, layer or surface.

Yet another object of the present invention is to provide a novel metal composition and passivation process characterized by simplicity of application.

Yet another object of the present invention is to provide a novel composition and process suitable to provide a dopant for a metal alloy or metal seed layer.

A still further object of the present invention is to provide a novel process which involves the spontaneous displacement of metal atoms in a metal with atoms of a second metal to substantially reduce or prevent oxidation of the metal.

Another object of the present invention is to provide a novel metal passivation composition and process suitable for increasing the Q-time between chemical mechanical planarization of a metal and deposition of an etch stop layer or other fabrication processing on the metal.

Yet another object of the present invention is to provide a novel metal passivation process which may be incorporated into a chemical mechanical planarization (CMP) process.

### SUMMARY OF THE INVENTION

In accordance with these and other objects and advantages, the present invention is generally directed to a novel composition and process suitable for the passivation of metal lines, layers or surfaces, particularly for the passivation of copper in the fabrication of integrated circuit devices on wafer substrates. The process includes providing a novel composition solution in contact with a typically copper line, layer or surface on a substrate as the copper is subjected to chemical mechanical planarization (CMP). The composition includes reactive cations of a displacement metal which are suspended in solution and spontaneously displace the copper atoms in the copper in an oxidation/reduction reaction. The oxidized and displaced copper cations are carried away by the composition solution, and the newly-incorporated metal atoms in the copper substantially inhibit or prevent growth of copper oxides in the copper. Consequently, the Q-time between CMP and deposition of an etch stop layer on the copper, for higher-order fabrication of metal lines and vias on the copper, for example, is prolonged. Furthermore, the electro-migration characteristics of the line, layer or surface having the reduced copper content are significantly enhanced.

The composition solution used in the passivation process of the present invention includes metal cations that are reduced and spontaneously displace copper atoms in a typically copper line, layer or surface to passivate the copper and substantially reduce or eliminate the growth of copper oxides in the copper, particularly on the copper surface. The displacement metal is incorporated into the copper or other metal at an atomic concentration of typically from about 40% to about 80% by weight. Other displacement metals suitable for the composition solution include silver, platinum and palladium, in non-exclusive particular.

The composition solution may further include a suppressor additive which suppresses the activity of copper or other metal. The displacement metal ion and suppressor additive may be provided in an aqueous acid solution to heighten the reactivity of the silver or other displacement metal ion. In a preferred embodiment, the aqueous acid solution is hydrochloric acid.

According to the process of the present invention, the composition solution is applied to the typically copper line, layer or surface during chemical mechanical planarization. The composition solution may be applied to the copper by dispensing the solution onto a polishing surface which subsequently contacts the copper. Alternatively, the solution may be applied to the copper by incorporating the solution into the polishing slurry used to polish the copper. The copper atoms in the copper are oxidized and the displacement metal cations in the composition solution are simultaneously reduced, such that the displacement metal atoms spontaneously displace the metal atoms in the copper. The displaced copper cations are carried away in the composition solution.

### BRIEF DESCRIPTION OF THE DRAWINGS

The invention will now be described, by way of example, with reference to the accompanying drawings, in which:

FIG. 1 is a graph indicating the atomic percentage of copper, oxygen and carbon in an untreated copper layer deposited on a substrate and exposed to ambient air;

FIG. 2 is a cross-sectional, partially schematic view of a CMP apparatus, illustrating one possible method of application of the composition solution according to the present invention;

FIG. 2A is a cross-sectional view of a wafer substrate with multiple conductive and insulative layers deposited thereon and a copper layer deposited on the top conductive layer;

FIG. 3 is a flow diagram summarizing typical process steps according to the method of the present invention;

FIG. 3A is a side view of a bath with the composition solution in which the copper can be immersed to form a passivation layer thereon; and

FIG. 4 is a graph indicating atomic percentages of copper, oxygen and carbon in a copper layer treated according to the process of the present invention and exposed to ambient air.

### DETAILED DESCRIPTION OF THE INVENTION

The present invention has particularly beneficial utility in the passivation of a typically copper line, layer or surface deposited on a semiconductor substrate in the fabrication of integrated circuits on the substrate. However, the invention is not so limited in application, and while references may be made to such semiconductor substrate and integrated circuits, the invention is more generally applicable to the passivation of conductive metals such as copper in a variety of industrial and mechanical applications.

In a preferred embodiment, the composition solution used in the passivation process of the present invention includes silver ions that are reduced and spontaneously displace copper atoms in a copper line, layer or surface to passivate the copper and substantially reduce or eliminate the growth of copper oxides in the copper, particularly on the copper surface. The silver ions may be present in the composition solution as silver sulfate, for example. The silver is incorporated into the metal at an atomic concentration of typically from about 40% to about 80% by weight. Other displacement metals suitable for the composition solution include silver, platinum and palladium, in non-exclusive particular. These metals have a reduction potential which is greater than that of copper. In a preferred embodiment, the displacement metal is present in the composition solution in a concentration of typically from about 10 g/l to about 50 g/l. Most preferably, the displacement metal is present in the composition solution in a concentration of typically about 10 g/l.

The composition solution typically further includes a suppressor additive which suppresses the activity of copper or other metal. The displacement metal ions and suppressor additive may be provided in an aqueous acid solution such as hydrochloric acid. The hydrochloric acid or other aqueous acid solution heightens the reactivity of the silver or other displacement metal ion. Preferably, the suppressor additive is present in the composition solution in a concentration of typically from about 10 g/l to about 50 g/l. Most preferably, the suppressor additive is present in the composition solution in a concentration of typically about 20 g/l. The hydrochloric acid or other aqueous solution has a concentration of typically about 200 ppm.

According to the process of the present invention, the composition solution is applied to the typically copper line, layer or surface during chemical mechanical planarization to remove copper overburden, or excess quantities of copper, from the copper line, layer or surface. The composition solution may be applied to the copper by dispensing the solution onto a polishing surface which subsequently contacts the copper. Alternatively, the solution may be applied to the copper by incorporating the solution into the polishing slurry used to polish the copper. In either case, the copper atoms in the copper are oxidized and the displacement metal cations in the composition solution are simultaneously reduced, such that the displacement metal atoms spontaneously displace the copper atoms in the copper according to the following equation:
Meⁿ⁺+Cu→Cu²⁺+Me
where Me is the displacement metal and n=an oxidation state of +1 (monovalent) or +2 (bivalent). Accordingly, the atomic percentage of copper in the copper layer is reduced and the atomic percentage of the displacement metal in the copper is correspondingly increased. Consequently, formation of copper oxides in the copper is eliminated, or at least, substantially reduced. While copper is used as an example of a metal which is suitable for passivation according to the composition and process of the present invention, it is understood that the process of the invention may be adapted to the displacement of other monovalent or bivalent metal atoms in metals other than copper.

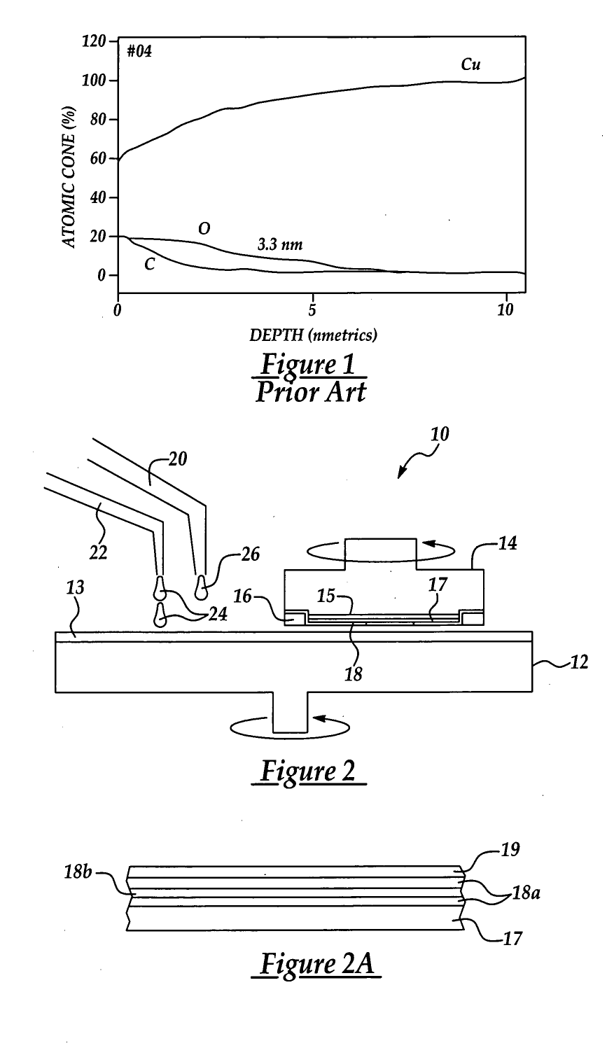

Referring to FIG. 2A, in the fabrication of semiconductor integrated circuits, multiple insulative layers 18a and conductive layers 18b are deposited on a typically silicon wafer substrate 17. The insulative layers 18a and conductive layers 18b are sequentially deposited on the substrate 17 and on each other in alternating order using techniques such as chemical vapor deposition (CVD) and physical vapor deposition (PVD), for example. Multiple vias (not shown) typically extend vertically through the insulative layers 18a and connect the horizontally-extending conductive layers 18b to each other. The conductive layers 18b serve as metal lines or layers which electrically connect device components to each other in the integrated circuits. The insulative layers 18a are an electrically-insulative dielectric material, and the conductive layers 18b are typically copper. The vias and metal lines or layers are fabricated in the insulative layers 18a and conductive layers 18b typically using a dual-damascene process, for example. An upper copper layer 19 is deposited on an insulative layer 18a, typically using CVD, PVD or electroplating techniques, for example. Prior to further fabrication of the devices on the substrate 17, the upper copper layer 19 typically requires CMP treatment to remove copper overburden therefrom, for example.

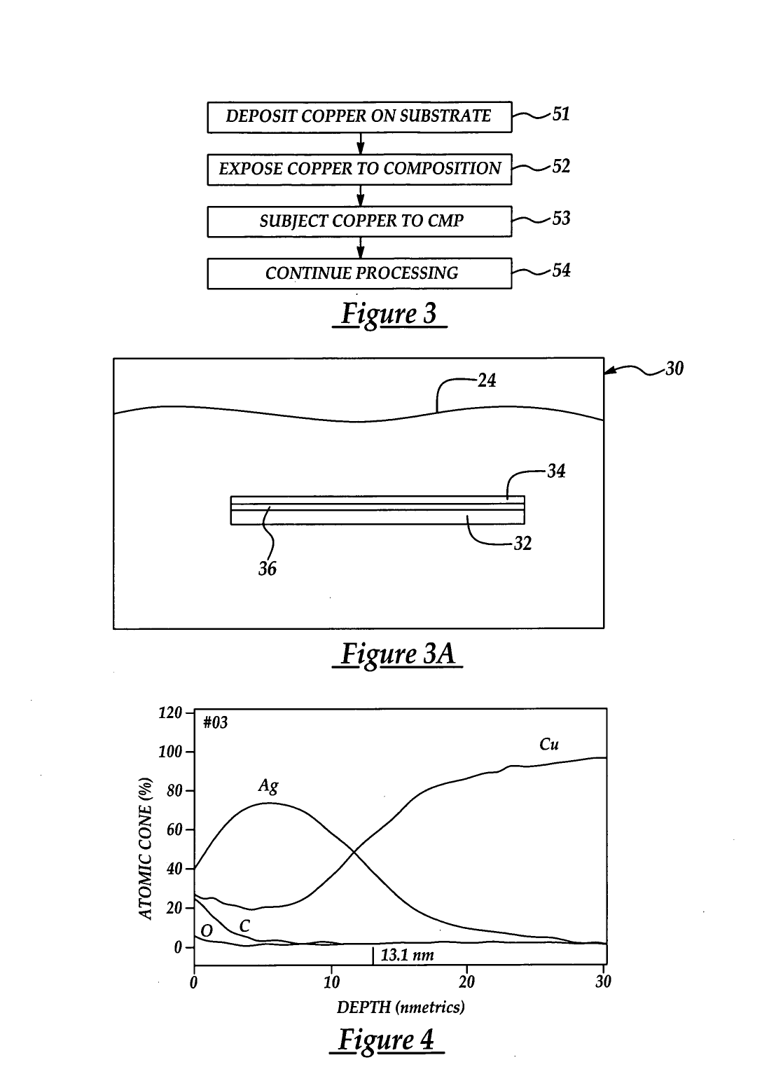

Referring next to FIGS. 2-4, according to the process of the present invention the copper layer 19 is deposited typically on an upper insulative layer 18a on the substrate 17, as shown in FIG. 2A and indicated in step S1 of FIG. 3. Preparatory to subsequent chemical mechanical planarization of the copper layer 19, the substrate 17 is attached to a substrate holder 14 of a CMP apparatus 10, as shown in FIG. 2. As is known by those skilled in the art, the retainer ring 16 typically secures the substrate 17 in an inverted position to the substrate holder 14, with the backside of the substrate 17 typically abutting against a backing pad 15. The substrate holder 14 is typically positioned above a polishing pad 13 mounted on a rotatable platen 12. While the CMP apparatus 10 shown in FIG. 2 is a rotary-type CMP apparatus, it is understood that the present invention is equally adapted to a linear-type CMP apparatus in which the substrate holder 14 is positioned above an endless, linearly-driven polishing belt (not shown).

As indicated in step S2 of FIG. 3, after the substrate 17 is mounted on the substrate holder 14 typically in the manner shown heretofore described with respect to FIG. 2, the copper layer 19 is exposed to the element-displacing composition solution of the present invention, as indicated in step S2. This may be carried out typically by first mixing the composition solution with the polishing slurry 26 prior to dispensing the polishing slurry 26 onto the polishing pad 13, typically from a slurry supply nozzle 20. The composition solution is present in the polishing slurry 26 in a concentration of typically about 100 ppm. Alternatively, the composition solution 24 may be applied to the copper layer 19 by dispensing the composition solution 24 directly onto the polishing pad 13, typically through a composition supply nozzle 22 positioned above the polishing pad 13, as shown in FIG. 2. In that case, the polishing slurry 26 is dispensed onto the polishing pad 13 through a separate slurry dispensing nozzle 20. Accordingly, the polishing pad 13 rotates the composition solution 24 dispensed thereon into contact with the copper layer 19 on the substrate 17, as the substrate holder 14 rotates the copper layer 19 against the polishing pad 13. Simultaneously, the copper layer 19 is polished by the polishing slurry 26 dispensed separately onto the polishing pad 13.

As the composition solution 24 contacts the copper layer 19, metal ions in the solution 24 are spontaneously reduced to displacement metal atoms, and copper atoms in the copper layer 19 are simultaneously oxidized to copper cations. Consequently, the reduced displacement metal atoms spontaneously replace the oxidized copper atoms in the copper layer 19, such that the atomic percentage of copper atoms is decreased and the atomic percentage of displacement metal is correspondingly increased in the copper layer 19. As a result, the copper layer 19 is rendered substantially resistant to copper oxide formation prior to resumption of semiconductor fabrication processing, as indicated in step S4 in FIG. 3. The oxidized copper ions displaced from the copper layer are carried away in the composition solution.

It will be appreciated by those skilled in the art that the substantially oxidation-resistant quality of the treated copper layer 19 permits the Q-time between chemical mechanical planarization of the copper layer 19 and subsequent deposition of an etch stop layer (not shown), for example, onto the copper layer 19 for higher-order fabrication of metal lines and vias, to be substantially prolonged. As a result, the electro-migration properties of the copper layer 19 in the finished IC devices are enhanced. It is understood that the copper layer 19, when treated according to the process of the present invention as described hereinabove, further serves as an effective cap layer when the copper layer 19 is the final conductive layer deposited on a substrate. Moreover, the process of the present invention is useful to provide a dopant for a copper alloy as such is needed in the fabrication of IC devices on a substrate.

FIG. 4 illustrates a graph which indicates atomic percentages of copper, oxygen and carbon in a copper layer treated according to the process of the present invention and exposed to ambient air. In the graph, displacement silver atoms have spontaneously displaced copper atoms in the copper layer. At the surface of the copper layer, the atomic concentration of silver is about 40%, and this atomic concentration of silver rises to about 75% at a depth of about 5 nm. The silver atomic concentration then gradually decreases to about 10% at a depth of about 30 nm. The atomic concentration of copper at each depth of the layer is inversely proportional to that of the displacement silver, and the atomic concentration of silver substantially equals that of copper at a depth of about 13 nm.

It is apparent from a consideration of the graph in FIG. 4 that the atomic concentration of oxygen at the surface of the copper layer is about 5%, and this oxygen concentration slightly decreases at increasing depths of the copper layer, and then stabilizes at depth of about 10 nm. This oxygen concentration at the surface of the copper layer treated according to the present invention is compared to an oxygen concentration of about 20% at the surface of an untreated layer of copper, as indicated in the graph of FIG. 1 and heretofore described. Accordingly, the composition and process of the present invention serve as an effective technique to substantially reduce the formation of copper oxides in a copper layer, particularly at the surface and upper regions of the layer.

Referring next to FIG. 3A, in which a bath container 30 which contains a supply of the composition solution 24 is shown. A passivation layer 34 can be formed on a copper layer 36 provided on a substrate 32, by immersing the substrate 32 with the copper layer 36 in the composition solution 24. The substrate 32 and copper layer 36 are immersed in the composition solution 24 for about 30 seconds to form a passivation layer 34 having a thickness of about 100 Å.

Prior to immersing the substrate 32 into the composition solution 24, the copper layer 36 may be patterned to form a metal interconnect line on the substrate 32. In that case, after immersion of the substrate 32 to form the passivation layer 34, the metal line is completed by chemical mechanical planarization of the passivated copper layer 36.

While the preferred embodiments of the invention have been described above, it will be recognized and understood that various modifications can be made in the invention and the appended claims are intended to cover all such modifications which may fall within the spirit and scope of the invention.

What is claimed is:

1. A composition for the displacement of metal atoms in copper, comprising:
a solution; and
a displacement metal provided in said solution for displacing the copper atoms in the copper, said displacement metal having a higher reduction potential than the copper.

2. The composition of claim 1 wherein said solution comprises a metal sulfate solution.

3. The composition of claim 1 wherein said displacement metal is silver, gold, platinum or palladium.

4. The composition of claim 3 wherein said solution comprises a metal sulfate solution.

5. The composition of claim 1 wherein said displacement metal is provided in said solution in a concentration of from about 50 ppm to about 200 ppm.

6. The composition of claim 5 wherein said solution comprises a metal sulfate solution.

7. The composition of claim 5 wherein said displacement metal is silver, gold, platinum or palladium.

8. The composition of claim 7 wherein said solution comprises a metal sulfate solution.

9. The composition of claim 1 further comprising a metal suppressor provided in said solution.

10. The composition of claim 9 wherein said metal suppressor is provided in said solution at a concentration of from about 10 g/l to about 50 g/l.

11. The composition of claim 9 wherein said solution comprises a metal sulfate solution.

12. The composition of claim 9 wherein said displacement metal is silver, gold, platinum or palladium.

13. A process for passivating a metal, comprising the steps of:
forming a metal line by subjecting said metal to chemical mechanical planarization; providing a composition having metal-displacing ions; and
contacting said metal with said composition.

14. The process of claim 13 wherein said contacting said metal with said composition comprises the steps of providing a polishing slurry, combining said composition with said polishing slurry and contacting said metal with said polishing slurry.

15. The process of claim 13 wherein said contacting said metal with said composition comprises the steps of providing a polishing pad, dispensing said composition on said polishing pad and contacting said metal with said polishing pad.17. A device made by the process according to claim 3

16. The process of claim 13 wherein said metal-deplacing ions are silver, gold, platinum or palladium.

17. A device made by the process according to claim 13.

18. The device of claim 17 wherein said metal-displacing ions are silver, gold, platinum or palladium ions.

19. A process for passivating a metal, comprising the steps of:
providing a composition having metal-displacing ions;
contacting said metal with said composition; and
forming a metal line by subjecting said metal to chemical mechanical planarization.

20. The process of claim 19 wherein said metal is a copper alloy.
